(19) United States
(12) Patent Application Publication
(10) Pub. No.: US 2026/0118410 A1
(43) Pub. Date: Apr. 30, 2026

(54) TECHNIQUES FOR ELECTRICAL CHARACTERIZATION OF LOGICAL CELLS IN INTEGRATED CIRCUIT TESTING SYSTEMS

(71) Applicant: FEI Company, Hillsboro, OR (US)

(72) Inventors: Weston Hearne, Plano, TX (US); Thomas A. Daniel, Frisco, TX (US)

(21) Appl. No.: 18/934,034

(22) Filed: Oct. 31, 2024

(51) Int. Cl. G01R 31/28

(52) U.S. Cl. CPC G01R 31/287; G01R 31/2879; G01R 31/2887

(57) ABSTRACT

Techniques for electrical characterization of a logical cell. A system can include a plurality of probes, control circuitry, bias circuitry, and machine-readable storage media storing instructions that, when executed by a machine, cause the machine to perform operations including landing the probes on a surface of an integrated circuit, including a plurality of electrically coupled transistors, the logical cell having been electrically isolated from one or more conductive structures of the integrated circuit. The operations can include applying one or more bias voltages to the logical cell via one or more of the probes, performing an operational test of the logical cell using the probes, and generating output data describing one or more logical states of the logical cell over at least a portion of the operational test.

### TECHNICAL FIELD

Embodiments of the present disclosure are directed to electronic testing systems, as well as algorithms and methods for their operation. In particular, some embodiments are directed toward techniques for integrated circuit testing.

### BACKGROUND

Integrated circuit (IC) testing typically involves measurement of individual transistors or groups of transistors of a semiconductor wafer or wafer section (e.g., a diced wafer), termed a “device under test” or DUT. Typically, probes are positioned in contact with integrated circuit elements and used to interrogate the DUT with a time-varying electrical signal. With increasing feature density and structural complexity of integrated circuits, it is desirable to characterize collective behavior of interconnected devices, termed “cells.” A cell can include multiple transistors arranged in a configuration that generates outputs representative of one or more logical states in response to one or more electrical input signals.

Interrogating the logical states of an integrated circuit cell is complicated by the highly coupled nature of DUTs. For example, power distribution nets typically electrically couple multiple cells, making leakage current a significant limitation. Further, impedance and other electrical behavior of IC cells can be cell-specific, making cell-level testing complex and challenging. There is a need, therefore, for improved electrical characterization techniques for IC testing systems to enable cell-level interrogation using probe-based systems.

### SUMMARY

Systems, methods, and techniques for electrical characterization of a logical cell are described. In an aspect, a system for electrical characterization of a logical cell includes a plurality of probes, control circuitry, bias circuitry, and one or more machine-readable storage media. The control circuitry can be electrically coupled with the probes. The bias circuitry can be electrically coupled with one or more of the probes and configured to apply a bias voltage to the one or more probes. The storage media can be electronically coupled with the control circuitry. The media can store instructions that, when executed by a machine, cause the machine to perform operations. The operations can include landing the probes on a surface of an integrated circuit, thereby electrically coupling the probes with the logical cell. The logical cell can include a plurality of electrically coupled transistors. The logical cell can have been electrically isolated from one or more conductive structures of the integrated circuit. The operations can include applying one or more bias voltages to the logical cell via one or more of the probes, using the bias circuitry. The operations can include performing an operational test of the logical cell using the probes. The plurality of transistors can together define an arrangement configured to generate an output voltage representative of one or more logical states of the logical cell in response to one or more input voltage signals. The operational test can be based at least in part on the arrangement. The operations can also include generating output data describing the one or more logical states of the logical cell over at least a portion of the operational test.

In some embodiments, landing the probes includes electrically coupling a first probe with a positive supply input of the logical cell and electrically coupling a second probe with a negative supply input of the logical cell. The second probe can coupled with a load, and wherein the method comprises measuring a voltage across the load.

Applying the bias voltages can include coupling a positive bias voltage into the first probe and coupling a negative bias voltage into the second probe. Landing the probes can include electrically coupling a first probe with a transistor gate of the logical cell and a second probe with an output terminal of the logical cell. Performing the operational test of the logical cell can include coupling a test signal into the logical cell via first probe. Generating the output data can include coupling a voltage signal out of the logical cell from the fourth probe.

In some embodiments, the output data includes voltage data, for which a positive value of the voltage corresponds to a first logical state of the logical cell under test. A negative value of the voltage can correspond to a second logical state of the logical cell under test. A zero value of the current can correspond to a fault in the signal.

In some embodiments, the arrangement defines a flip-flop. The plurality of probes can include eight or more probes. Landing the probes can include coupling a first probe with a positive supply input of the logical cell, coupling a second probe with a negative supply input of the logical cell, coupling a third probe with a test signal input, “D,” of the logical cell, coupling a fourth probe with a clock signal input of the logical cell, and coupling a fifth probe with an output of the logical cell. Performing the operational test can include coupling the test signal into the logical cell via the third probe. The test signal can describe a duty cycle of the flip-flop. Performing the operational test can include coupling the clock signal into the logical cell via the fourth probe. The clock signal can be characterized by a clock frequency from about 1 MHz to about 10 GHZ. Generating the output data can include coupling voltage data out of the logical cell from the fifth probe.

In some embodiments, the surface of the integrated circuit can correspond to a metallization layer of the integrated circuit, Mn. The integrated circuit can define a trench in the metallization layer Mn at least partially surrounding the logical cell. The trench can be formed through a subordinate layer, Mm, below the metal layer Mn. The conductive structures can include power distribution nets. A probe of the plurality of probes can be coupled with a circuit element configured to improve a quality of an alternating current signal coupled into the logical cell via the probe.

In an aspect, one or more non-transitory machine-readable storage media storing instructions that, when executed by a machine, cause the machine to perform operations of the preceding aspect in one or more embodiments, alone or in combination.′

In an aspect, a method for electrical characterization of a logical cell can include operations of the preceding aspect in one or more embodiments, alone or in combination.

Embodiments of the present disclosure include systems, components, and methods in accordance with the preceding aspects. The terms and expressions which have been employed are used as terms of description and not of limitation, and there is no intention in the use of such terms and expressions of excluding any equivalents of the features shown and described or portions thereof, but it is recognized that various modifications are possible within the scope of the claimed subject matter. Thus, it should be understood that although the present claimed subject matter has been specifically disclosed by embodiments and optional features, modification and variation of the concepts herein disclosed can be resorted to by those skilled in the art, and that such modifications and variations are considered to be within the scope of this disclosure as defined by the appended claims.

### BRIEF DESCRIPTION OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram illustrating an example integrated circuit testing system, in accordance with some embodiments of the present disclosure.

FIG. 2A and FIG. 2B are schematic diagrams illustrating an example device under test prepared for interrogation of a logical cell, in isometric perspective and in section, respectively, in accordance with some embodiments of the present disclosure.

FIG. 3 is a schematic diagram illustrating an example integrated circuit testing probe in plan view, in accordance with some embodiments of the present disclosure.

FIG. 4 is a schematic diagram illustrating an example integrated circuit testing probe in profile view, in accordance with some embodiments of the present disclosure.

FIG. 5 is a schematic diagram illustrating an example integrated circuit testing system including multiple probes, in accordance with some embodiments of the present disclosure.

FIG. 6 is a block flow diagram illustrating an example process for electrical characterization of a logical cell, in accordance with some embodiments of the present disclosure.

FIGS. 7A-7D illustrate an example voltage inverter cell and example signals generated through interrogation of the example cell, in accordance with some embodiments of the present disclosure.

FIGS. 8A-8D illustrate an example d-flip flop cell and example signals generated through interrogation of the example cell, in accordance with some embodiments of the present disclosure.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

While illustrative embodiments have been illustrated and described, it will be appreciated that various changes can be made therein without departing from the spirit and scope of the disclosure. In the forthcoming paragraphs, embodiments of an analytical instrument system, components, and methods for interrogating logical cells. In the context of this description, a logical cell includes multiple electrically coupled transistors that together define an arrangement configured to generate an output voltage representative of one or more logical states of the logical cell in response to one or more input signals. To that end, logical cells of the present disclosure can include arrangements of one or more logic gates, as employed in memory circuits, logic circuits, or the like.

Embodiments of the present disclosure focus on integrated circuit characterization and failure analysis of transistor arrangements in the interest of simplicity of description. Embodiments are not limited to such instruments, but rather are contemplated for analytical instrument systems configured for interrogating integrated circuit devices at a cell-scale.

Embodiments of the present disclosure include systems, methods, algorithms, and non-transitory media storing machine-readable instructions for electrical characterization of a logical cell (e.g., interrogating the logical cell via one or more operational tests of the logical cell). Technical advantages of the present disclosure include electrical fault analysis of logical cells at the cell-level, with higher-order logical states of the cell being interrogated, in contrast to device-level probing that is typical of current techniques in which individual integrated circuit devices (e.g., transistors) are contacted, powered, and tested. Interrogating logical cells permits fabrication defects between devices to be revealed, such as short circuits between different logic gates, that would not be immediately apparent in device-level probing, as well as identifying faults in cell-level operation.

Integrated circuit testing typically involves measurement of individual transistors or groups of transistors of a semiconductor wafer or wafer section (e.g., a diced wafer), termed a “device under test” or DUT. In the context of the present disclosure, DUT is used in the context of cell-level interrogation that includes powering multiple interconnected devices and inputting one or more test signals while measuring one or more output signals. Probes can be positioned in electrical contact with integrated circuit elements and used to interrogate the DUT with periodic, aperiodic, and/or direct current electrical signals. One or more probes are used as inputs and one or more probes are used as outputs to measure the response of the IC elements to the signal.

With increasing feature density and structural complexity of integrated circuits, placing probes onto specific IC elements involves nanoscale geometries of probe tips and nanoscale information for the probe tip position. While technically possible, precise positioning of probe tips onto conducting contacts at the nanometer scale, corresponding to a characteristic feature size of current CMOS nodes, can increase the complexity of control systems to an extent that it is impractical at the scale on which testing platforms are deployed.

In parallel with the development of new systems to improve precision of probe tip placement, embodiments of the present disclosure are addressed at interrogating arrangements of coupled devices at higher metallization layers, rather than probing individual devices, thereby benefiting from relatively larger spatial constraints on placement of probe tips and enabling systems to characterize higher-level operation of interconnected devices (e.g., logic states of the cell).

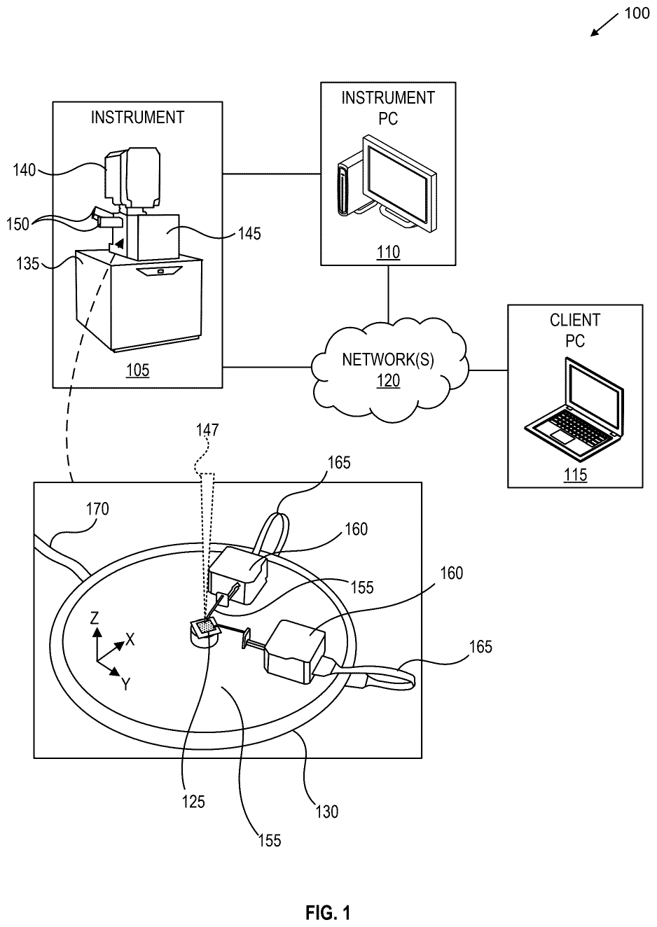

Relative to existing techniques, embodiments of the present disclosure enable cell-level interrogation, based at least in part on electrically isolating one or more logical cells from the power distribution nets of the DUT. As an illustrative example, logical cells that can be interrogated in this manner include, but are not limited to, voltage inverter cells, d-flip flop cells, dual flop cells, NAND gates, combinational logic cells, conditional logic cells, or the like. As described in more detail in reference to FIGS. 1-8D, embodiments of the present disclosure permit a system of probes to be precisely located and lowered onto contacts through which a logical cell can be powered and interrogated.

FIG. 1 is a schematic diagram illustrating an example integrated circuit (IC) testing system 100, in accordance with some embodiments of the present disclosure. The example system 100 includes an instrument 105, an instrument computing device (IPC) 110, and a client computing device 115, operably intercoupled via one or more networks 120. The example system 100 is configured to interrogate an IC device, termed a device under test (DUT) 125 using probe assembly 130, electronically coupled with components of the DUT 125 via a controller, also referred to as a test rig. Through application of time-varying electronic signals to components of the DUT 125, termed a “test loop,” performance characteristics of circuit components of the DUT 125 can be derived as part of quality control and failure analysis techniques for ICs fabricated according to a given IC design.

The instrument 105 includes a test section 135 in which the probe assembly 130 is disposed, including the DUT 125 as well as the electronic components to drive the test loop (e.g., the test rig), vacuum components to isolate the DUT 125 from atmosphere, and thermal management systems to remove heat from the DUT 125 during testing. Coupled with the test section 135 are a charged particle column 140 and a vacuum chamber 145. The charged particle column 140 can be an ion beam (e.g., focused ion beam (FIB)) column or an electron beam column. In some embodiments, the instrument 105 includes a FIB column and an electron beam column with one of the columns being coupled with the vacuum chamber at an angle relative to the charged particle column 140.

An electron beam column can generate a beam of electrons 147 and focus the beam of electrons 147 onto the DUT 125. The interaction of the beam of electrons 147 with the DUT 125 gives rise to one or more detectable signals, which can be received by one or more detectors 150 operably coupled with the vacuum chamber 145 and configured to generate detector data based at least in part on measurement of the signal(s). In an illustrative example, the detector(s) 150 can include secondary electron detectors, backscattered electron detectors, photon detectors, imaging sensors (e.g., CCDs) or the like.

In contrast to a typical scanning electron microscope (SEM), the vacuum chamber 145 can omit sample manipulation tools, such as an interlock, sample stage, and the like, at least in part because the DUT 125 can be removably coupled with the probe assembly 130, which can be disposed on a stage, a cradle, or other retention assembly that provides electronic and thermal coupling with the test section (e.g., coupled with the test rig). The beam of electrons 147 can be directed toward the DUT 125 using various operational modes, including but not limited to imaging mode, line scan mode, and spot mode.

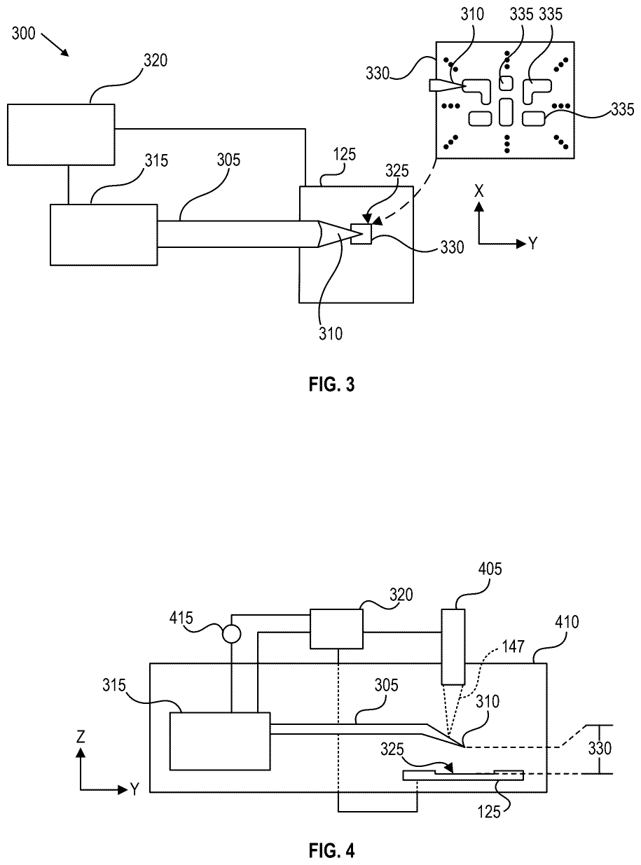

The probe assembly 130 can include individually addressable probes 155, movable in three spatial dimensions (labeled with “x-y-z” cartesian axes) by electromechanical actuators 160. In this way, probe tips (labeled 310 in reference to FIGS. 3-4) can be displaced toward a position on the surface of the DUT 125 with nanometer-scale precision. In some embodiments, the probe assembly 130 is electronically coupled with components of the test section 135 via couplings 165 and 170, by which the actuators 160 can be driven (e.g., using drive signals).

The computing devices 110 and 115 can be general-purpose machines (e.g., laptops, tablets, smartphones, servers, or the like) that are configured to operate or otherwise interact with the instrument 105. The instrument 105, in turn, can include electronic components that form part of a special-purpose computing device, including control circuitry configured to drive the test loop, actuate the probe assembly 130, control the electron beam column 140 and/or FIB column, and operate the vacuum systems and thermal management systems.

The IPC 110 can be a machine provided with software configured to interface with the instrument 105 and to permit a user of the instrument 105 to conduct a test of the DUT 125. Similarly, the client pc 115 can be configured to control one or more systems of the instrument 105 (e.g., via the IPC 110 and/or by interfacing with the instrument 105 over the network(s) 120) to conduct a test of the DUT 125. In some embodiments, the instrument 105, the IPC 110, and/or the client PC 115 are in separate physical locations and are coupled via the network(s) 120 and/or by other means, such as direct connection or by wireless connection (e.g., near-field radio). The network(s) 120 can include public networks (e.g., the internet) and/or private networks (e.g., intranet or local area networks). In some embodiments, the IPC 110 and/or the client PC 115 is/are configured to operate the instrument autonomously (e.g., without human intervention) or semi-autonomously (e.g., with limited human intervention, such as initiating a test, identifying a sample, and/or confirming an automated analytical result). In this way, the example system 100 can be configured to operate with human control and/or autonomously, as part of a scalable IC characterization system for automated testing of ICs.

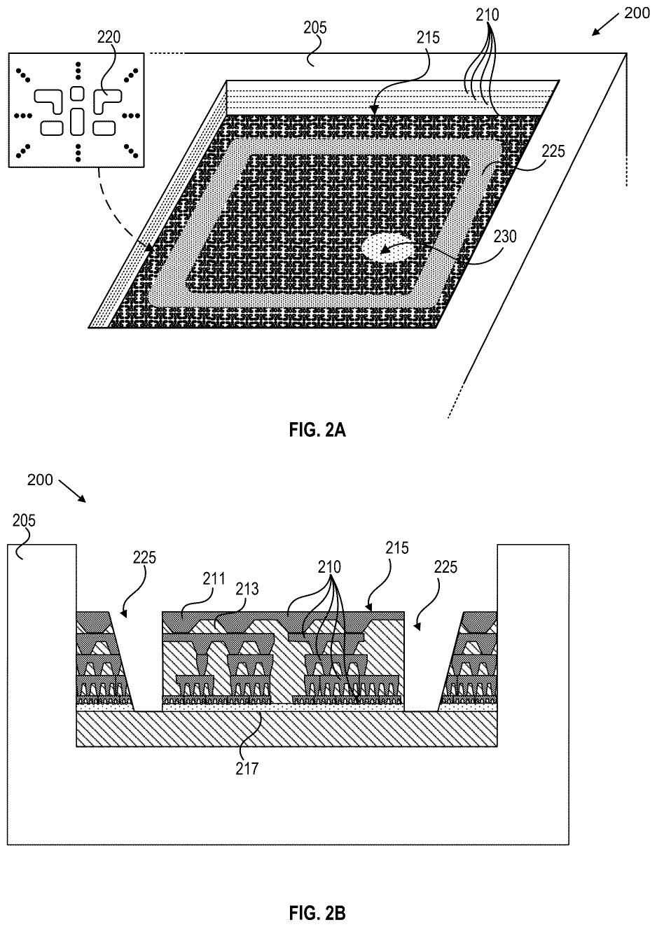

FIGS. 2A-2B is a schematic diagram illustrating an example device under test 200 prepared for interrogation of a logical cell, in accordance with some embodiments of the present disclosure. The device under test (DUT) 200 is shown as a portion of the DUT 125 of FIG. 1 and includes a substrate 205 of multiple layers 210 from which a portion has been removed to reveal at least a partial surface 215 of one of the layers 210. The surface 215 includes features 220 that electrically couple the surface 215 with electronic devices, such as transistors, of the DUT 200, such that electrically coupling probe(s) 155 of the example system 100 of FIG. 1, with the feature(s) 220 permits the example system 100 to interrogate the logical cell(s) of the DUT 200 that are accessible via the surface 215. The surface 215 defines a trench 225 formed in one or more layers 210 and at least partially surrounding a region of interest (ROI) 230 of the surface 215, in which the features 220 corresponding to a given logical cell are located. As shown, the trench 225 can isolate a relatively larger portion of the surface 215 than the ROI 230 alone, such that multiple instances of a given logical cell and/or various cell types can be interrogated in a single DUT 200.

In some embodiments, the DUT 200 is prepared by delayering with a focused ion beam (FIB) to expose the surface 215 and constituent features 220 (e.g., electrical contacts). For example, a plasma-FIB (PFIB) can be used to expose one or more metal layers 210, Mi, which are designated with an integer index relative to each layer's proximity to the device layer 217 (with the closest layer being indexed zero or one). In the context of CMOS integrated circuits, layers 210 can include a conductor 211 formed in a dielectric 213 matrix in multiple layers, by which the devices at the device layer 217 can be electrically coupled into arrangements configuring the devices to operate as logic gates, and further arranged into circuits configured for functional operation, such as flip-flops, dual flops, conditional logic, or the like.

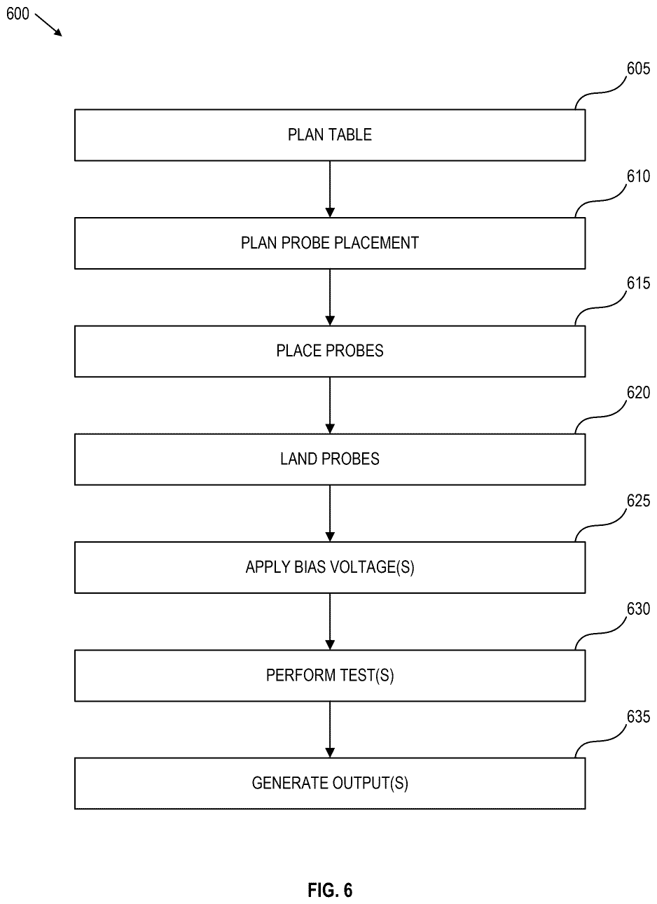

Prepared in this way, the inputs and outputs of the logical cell can be accessed without removing the interconnections between constituent devices of the cell, which can be formed in an intervening metal layer 210, between Mi and the device layer 217. In some embodiments, ion-beam techniques can be supplemented with mechanical techniques (e.g., mechanical dimpling, polishing, etc.) to remove at least a portion of overlying metallization prior to further processing by PFIB. As described in more detail in reference to FIG. 1, above, systems of the present disclosure can include a FIB instrument and/or dual-beam instrument, such that the preparation of DUT samples can be performed as part of an automated, pseudo-automated, and/or manual failure analysis protocol for quality assurance (e.g., as part of a semiconductor fabrication process). To that end, a diced wafer that has been mechanically dimpled can be further processed by PFIB to form the trench 225 prior to being loaded into an instrument configured to perform operational tests as described in reference to FIG. 6.

Probes of the present disclosure (e.g., probes 155 of FIG. 1, probes 300 of FIGS. 3-4, etc.) can be current limited with respect to the current that can be drawn through a single probe before resistive heating melts or deforms the probe tip. This sensitivity to current is based at least in part on the characteristic dimensions of the probe tip, defining a width on the order of 10-100 nm. In the context of interrogating logical cells of the present disclosure, current limitation presents a constraint on powering supply voltage (Vdd) and relative ground voltages (Vss) at upper metal layers. Advantageously, the trench 225 electrically isolates the logical cell(s) within the boundary defined by the trench 225 from the surrounding power distribution nets, thereby reducing the steady state current leakage of the circuitry to a magnitude at which the probe tips can power the cell with negligible or no thermal deformation or melting.

In an example, the trench 225 can be formed in the M₀ layer around the ROI 230, including a logical cell of interest for interrogation. In this context, the M₀ layer corresponds to the metallization layer nearest to the device layer. Isolating the ROI 230 in this way can limit the leakage current from Vdd to Vss to a value from about 100 μA to about 400 μA, a level that is typically within the tolerance of probes. In some embodiments, the trench 225 can be formed in a subordinate layer 210 of the DUT 200 below a given metal layer, Mₙ, where being Mₙ defines the surface 215. To that end, the trench 225 can interrupt power distribution nets at a layer Mₘ, where m is an integer less than n. In the example where n=0, the subordinate layer can include at least a portion of the device layer 217.

FIG. 3 is a schematic diagram illustrating an example integrated circuit testing probe 300 in plan view, in accordance with some embodiments of the present disclosure. The probe 300 is an example of the probes 155 of FIG. 1. The probe 300 includes a probe arm 305 and a probe tip 310. The probe 300 also includes electromechanical actuator(s) 315 (e.g., actuators 160 of FIG. 1). The probe 300 can be operably coupled with control circuitry 320 (e.g., via couplings 165 and 170 of FIG. 1), as described in reference to FIG. 1.

The probe arm 305 and probe tip 310 can be fabricated from a conductive wire that has been shaped and sharpened to a point. As illustrated in FIG. 1, the probe tip 310 can be oriented at an angle relative to the probe arm 305, such that the tip 310 contacts the surface 325 of the DUT 125 in a target area 330. The probe tip 310 can taper to a terminal surface having a characteristic dimension on the same scale as one or more features 335 of the DUT 125 (e.g., on the order of 1-100 nm). The feature(s) 335 can be conductive and electronically coupled with one or more IC components (e.g., transistors, diodes, etc.). For example, the feature(s) 335 can include conductive contact pads formed in one or more layers of the IC that can be used to mechanically and/or electrically couple the probe(s) 305 with the IC components.

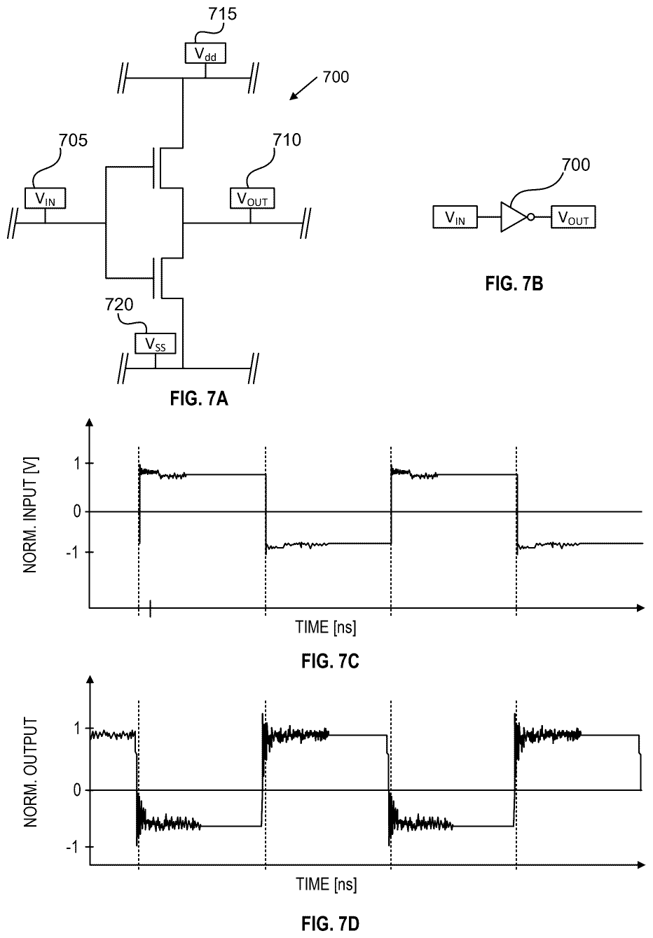

The probe tip 310 can be brought into contact with the surface 325 at a feature 335, electronically coupling the control circuitry 320 with the DUT 125. The coupling can permit a probe 300 to apply at least part of a test signal to the DUT 125 through a feature 335. In some embodiments, multiple probes 300 are contacted with multiple respective features 335 on the surface 325 and deployed concurrently to apply the test signals and to measure output signals. An example configuration with multiple probes 300 is described in reference to FIGS. 7A-7C.

The control circuitry 320 can drive the actuator(s) 315 in one or more directions, for example, by encoding a motion of the probe 300 as a vector of displacement values. The motion can include a component of linear motion (e.g., a linear displacement in one or more directions) in one or more degrees of freedom. For example, the probe 300 can include a three-axis motion system, configuring the probe tip 310 to be displaced relative to the surface 325 of the DUT 125 in one, two, and/or three orthogonal directions (e.g., an x-y-z coordinate space).

FIG. 4 is a schematic diagram illustrating the example integrated circuit testing probe 300 of FIG. 3 in profile view, in accordance with some embodiments of the present disclosure. FIG. 4 shows the probe arm 305, the probe tip 310, the actuator(s) 315, the control circuitry 320, the surface 325 of the DUT 125, as described in more detail in reference to FIG. 3, as well as other components including an imaging system 405 (e.g., an electron microscope, a focused ion beam source, and/or an optical microscope), a vacuum chamber 410 (e.g., an example of vacuum chamber 145 of FIG. 1), and one or more sensors 415 operably coupled with the probe 300.

In FIG. 4 the surface 325 is shown recessed into the DUT 125 to reflect that typically the features 335 are formed internal to the DUT 125 and are revealed by selective removal of material from the DUT 125 (e.g., by ion-beam milling or other etching processes), as illustrated in FIGS. 2A-2B. The probe tip 310 is shown at a displacement 420 from the surface 325. In some embodiments, example processes of the present disclosure include interrogating a logical cell of the DUT 125, as described in reference to FIG. 6. Control circuitry 320 can include one or more electronic signal filters and other components to process signals generated by the detector(s) 150. For example, the filters can include one or more lock-in amplifier(s), bandpass filters, low-pass and/or high-pass filters, or the like, configured to isolate frequency components, voltage components, current components, or the like, of the detector data attributable to various logical states of the logical cells of the DUT 125.

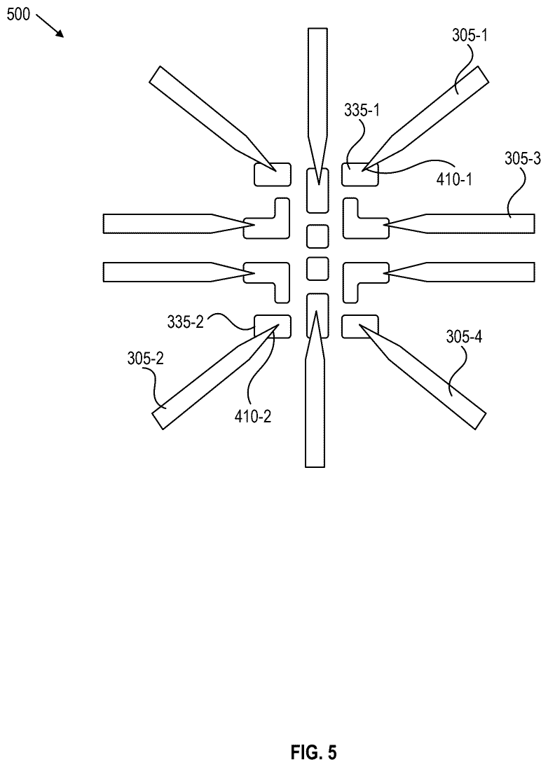

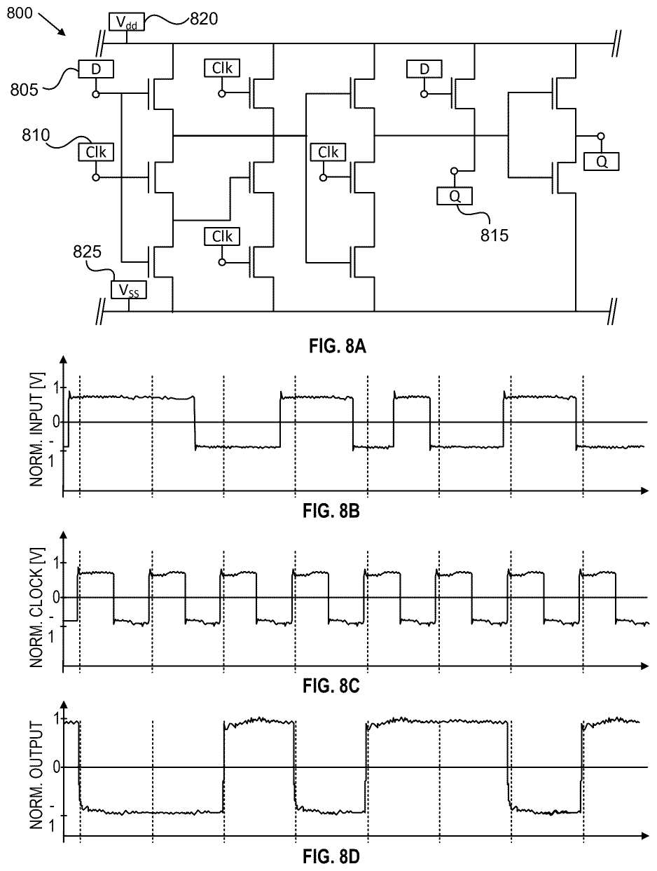

The beam of charged particles 147 can be directed toward a region of the probe 300 that can include the probe tip 310, as part of mapping a set of landing position(s) on the surface 325 and landing the probe tip 310 at an appropriate feature 335, corresponding to a given node of a logical cell. A logical cell can define multiple nodes at which various signals can be provided to the circuit and/or measured, such as a duty-cycle drive signal, a clock signal, and/or one or more output signals, as described in more detail in reference to FIGS. 7A-8B. Motion and action of the probe 300 can be coordinated with one or more additional probes as part of evaluating a logical cell, as described in more detail in reference to FIGS. 5-6. To that end, the control circuitry 220 can include and/or be coupled with arrays of switches, function generators, oscilloscopes, or the like, such that the systems of the present disclosure are configured to input multiple different signals into a logical cell, as well as measure one or more output signals and/or node voltage signals, as part of assessing fault status of the logical cell. In some embodiments, the probe system includes bias circuitry 415 configured to apply a bias voltage to the probe 300. The bias circuitry 415 can be configured to apply a positive bias voltage to the probe 300 or a negative bias voltage to the probe. The bias voltage can permit the probe to provide a supply voltage (e.g., Vcc, Vdd, etc.) and or a relative ground voltage (e.g., Vee, Vss, etc.). To that end, the relative ground voltage can be biased relative to a true ground potential, such that the supply voltage is positively biased relative to the true ground potential and the relative ground voltage is negatively biased relative to the true ground potential.

FIG. 5 is a schematic diagram illustrating an example integrated circuit testing system 500 including multiple probes, in accordance with some embodiments of the present disclosure. The probes of FIG. 5 are examples of the probes 155 and 300 of FIGS. 1-4. The system 500 illustrates ten individual probes that each make contact with a respective feature 335. For example, a first probe tip 410-1 can contact a first feature 335-1 and a second probe tip 410-2 can contact a second feature 335-2. The systems of the present disclosure can accommodate multiple probes, each individually employing the techniques described herein to power and/or interrogate a logical cell. The probe assembly (e.g., probe assembly 130 of FIG. 1) can accommodate 1-12 probes, including subranges and interpolations thereof. In some embodiments, systems of the present disclosure can accommodate more than 12 probes in a configuration for interrogating relatively complex circuits, such as dual-flop circuits or the like.

FIG. 6 is a block flow diagram illustrating an example process 600 for electrical characterization of a logical cell, in accordance with some embodiments of the present disclosure. One or more operations of the example process 600 can be executed by a computer system (e.g., IPC 110 of FIG. 1, Client PC 115 of FIG. 1, etc.) in communication with additional systems including, but not limited to, characterization systems, network infrastructure, databases, and user interface devices. For example, the systems can include multiple probes (e.g., probes 155 of FIG. 1, probe 300 of FIGS. 3-4, etc.), control circuitry (e.g., control circuitry 320 of FIGS. 3-4), electrically coupled with the probes, and bias circuitry (e.g., control circuitry 415 of FIG. 4), electrically coupled with one or more of the probes and configured to apply a bias voltage to one or more of the probes. To that end, some operations of the example process 600 can be encoded in one or more machine-readable storage media electronically coupled with the control circuitry.

In some embodiments, at least a subset of the operations described in reference to FIG. 6 are performed automatically (e.g., without human involvement) or pseudo-automatically (e.g., with human initiation or limited human intervention). In an illustrative example, operations for planning a waveform or logic table, planning probe-to-pad placement, terminating and cabling probes, and placing and landing probes, can be executed by a combination of automated and manual operations, with the system 100 being configured to automatically generate visualization data showing one or more response signals for interpretation by a human user (example shown in FIG. 6). While example process 600 is described as a sequence of operations, it is understood that at least some of the operations can be omitted, repeated, and/or reordered. In some embodiments, additional operations precede and/or follow the operations of example process 600 that are omitted for clarity of explanation, for example, operations for calibration of the electron source, alignment and aberration correction of the beam of electrons, initializing probe position or the like.

At operation 605, example process 600 includes planning waveform and/or logic table(s) for a given logical cell. In the context of the present disclosure, waveform tables refer to an attribution of a given signal to a given probe, based at least in part on the relative location of the probe and the configuration of the probe with respect to control circuitry. To that end, a subset of probes can be identified for powering the logical cell, one or more probes for supplying input signals (e.g., input voltage test signals, clock signals, etc.), and one or more probes for measuring output voltages at one or more nodes in the logical cell (e.g., Vout 710 in FIG. 7A, Q 820 in FIG. 8A, etc.). Techniques for waveform planning can include manual pattern generation and/or automated pattern generation. In an illustrative example, a list of input signals are generated representing some or all combinations of the inputs and levels of each respective signals, and generating corresponding outputs for the cell at each combination. With the set of input waveforms and the output of the cell so defined, synthetic test signal waveforms can be generated in accordance with a loss function that optimizes one or more criteria, such as the shortest signal length to identify those input conditions and/or combinations that can affect the output. Larger sets of waveforms can be used to arrive at the same or similar parametric solution, such as a linear combination signal where all possible inputs are considered. Additionally or alternatively, automated pattern generation can determine likely failures to be tested and generate a pattern as part of a signal defined to test the likely subset of conditions. In some cases, as in larger or more complex circuits, sampling a subset of likely test conditions can reduce the duration of the test, where a longer set of combinations would introduce delays in a test protocol.

Operation 605 can include generating a corresponding logic table defining expected output values for the waveforms that indicates whether the logical cell is operating within nominal parameters, such that faults can be detected in high frequency data. For example, in the simple example of the voltage inverter cell of Example 1, the logic table for a NOT cell corresponds a simple sign inversion condition of the waveform. Generating the logic table can also include examining the expected behavior and/or function of a circuit and creating a representative test pattern, rather than an exhaustive list of all combinations of inputs. In an example, a flip flop circuit includes as inputs a voltage input signal (D) and a clock signal, where the clock is oscillating periodically, and the D represents data patterns. To that end, operation 605 can include an expected set of interactions from which the output signal can be generated, rather than a table of the combinations of the two.

At operation 610, example process 600 includes planning probe placement. As described in more detail in reference to FIGS. 2A-5, metallization layers can include features (e.g., features 220 of FIG. 2A, features 335 of FIG. 3, etc.) that can be electrically coupled with nodes of a logical cell, where such features are also referred to as “contact pads” in the context of probe placement. In the example of the inverter cell in FIG. 7A, a contact pad can be electrically coupled with the gates of the two transistors, such that a probe assigned to supply a test signal can be placed to electrically couple with the contact pad. Correspondingly, the contact pads that are coupled with the power distribution nets of the cell and the output node of the cell can be located and the corresponding probes can be routed to those locations (e.g., in reference to design documentation, such as CAD of the circuit, which gives the relationship between physical structures of the DUT and the logical design of the cell(s)). In some embodiments, operation 610 can include receiving, generating, and/or referencing location information describing the exposed layer of the integrated circuit (e.g., ROI 230 of FIG. 2A). The location information can include images of the surface of the integrated circuit (e.g., secondary electron image data generated using the charged particle column 140 and the detectors 150 of the system 100 of FIG. 1), such that a three-dimensional position of the probe tip corresponding to the appropriate contact pad can be determined. In this way, a position of each probe that is to be used to interrogate the logical cell can be planned, relative to the surface of the integrated circuit.

At operation 615, example process 600 includes placing terminators and arranging cabling to probes. As described in more detail in reference to FIGS. 1-5, power, test signals, and output signals can be generated and coupled into/out of the logical cell as part of example process 600. To that end, control circuitry for the systems of the present disclosure include variable, interchangeable, and/or modifiable elements that are specified as part of a given operational test. Circuit elements can be placed to account for electrical characteristics of probe circuits including, but not limited to, resistance, impedance, current, and/or voltage constraints. For example, the characteristic impedance of the corresponding probe circuit can influence the characteristic frequency and power of an input signal, such that the electrical circuit components can be determined to match the impedance and improve signal transfer into the logical cell. Similarly, electrical cabling is selected for each probe, based at least in part on the role assigned to each probe for a given operational test. Operation 615, therefore, can include determining, configuring, and coupling electrical circuit components and cabling for each of the probes that is part of a given operational test. In an illustrative example, probes that will be used to couple an alternating current signal (e.g., test signal probes) into the DUT can include circuit elements coupled with the probe to improve the signal quality into or out of the DUT, while probes that will be used to couple a direct current signal (e.g., power supply probes) into the DUT can omit such circuit elements. Probe placement can be constrained by the location(s) of the circuit elements configured to such purposes, as when a subset of the probes are coupled with such circuit elements. To that end, operation 615 can include planning probe termination as well as placement, based at least in part on assessing pad structure in the ROI and physical space available on the surface of the DUT for probe placement, to spatially plan where to put terminator(s).

At operation 620, example process 600 includes landing the probes on a surface of an integrated circuit. As described in more detail in reference to FIGS. 2A-3B, the surface of the integrated circuit can correspond to at least part of a metallization layer, such that landing the probes at appropriate features on the surface can electrically couple the probes with corresponding nodes of the logical cell. The logical cell, in turn, includes a plurality of electrically coupled transistors that have been electrically isolated from one or more conductive structures of the integrated circuit. For example, the logical cell can be electrically isolated from power distribution nets of the integrated circuit using a trench (e.g., the trench 225 of FIGS. 2A-2B).

In some embodiments, operation 620 can include one or more sub-operations of the electromechanical elements of the probe assembly (e.g., actuator 160 of FIG. 1, actuator 315 of FIG. 3, etc.) to place the probes in a two-dimensional plane above the surface of the integrated circuit. In this way, landing can include motion that is isolated in a plane parallel to the surface, followed by motion isolated in a line normal to the surface. In this way, the placement of the probe tip onto an appropriate contact pad can be precisely controlled, with negligible or no lateral motion near the surface. Advantageously, reducing or eliminating lateral motion can limit the risk of damaging the surface by lateral motion after an undetected contact of the probe with the surface.

Landing the probes can include electrically coupling a first probe with a positive supply input of the logical cell and electrically coupling a second probe with a negative supply input of the logical cell. In this way, applying the bias voltages at operation 625 can include coupling a positive bias voltage into the first probe and coupling a negative bias voltage into the second probe. Landing the probes can include electrically coupling an input probe with a transistor gate of the logical cell, such that an input signal can be provided. Where an output probe is coupled with an output terminal of the logical cell, the cell can be powered and interrogated by powering the cell with the first and second probes and supplying an input signal via the input probe.

In the example of a flip flop cell, demonstrated in Example 1 and FIGS. 7A-7D, below, the system can include five or more probes, and landing the probes can include coupling a first probe with a positive supply input of the logical cell, coupling a second probe with a negative supply input of the logical cell, coupling a third probe with a test signal input, “D,” of the logical cell, coupling a fourth probe with a clock signal input of the logical cell, and coupling a fifth probe with a voltage output of the logical cell. Where additional probes are available, and the system is configured for additional output channels, landing the probes can also include coupling a sixth probe with a first node of the logical cell, coupling a seventh probe with a second node of the logical cell, and coupling an eighth probe with a third node of the logical cell. In this way, flip flop cell can be interrogated, as described in reference to operation 630, below.

At operation 625, example process 600 includes applying one or more bias voltages to the logical cell via one or more of the probes. The bias voltages can include a supply voltage (e.g., V_{cc}, V_{dd}, etc.) and a relative ground voltage (e.g., V_{EE}, Vₛₛ, etc.). In contrast to typical probing configurations, operation 625 can include supplying a negative, nonzero, relative ground voltage. For example, the supply voltage can be from about 0 V to about 10 V, including subranges, fractions, and interpolations thereof, and the relative ground voltage can be from about 0 V to about −10 V, including subranges, fractions, and interpolations thereof. Advantageously, powering a logical cell with a negative relative ground voltage can eliminate confounding effects of nominal zero-current operation with NMOS faults in transistors of the logical cell.

At operation 630, example process 600 includes performing an operational test of the logical cell using the probes. As described in reference to FIGS. 2A-2B and in the Examples 1-2, below, the plurality of transistors can together define an arrangement configured to generate an output voltage representative of one or more logical states of the logical cell in response to one or more input voltage signals. In this way the operational test can be based at least in part on the arrangement, as described in reference to operations 605-610. Operational tests can include powering to the logical cell via two probes, coupling a test signal into the logical cell via one or more input probes.

In the context of a d-flip flop cell, operation 630 can include coupling a test signal into the logical cell via the third probe. The test signal can describe example data of the flip-flop (e.g., the D-signal 805 of FIG. 8A). Operation 630 can include coupling the clock signal (e.g., the CLK signal 810 of FIG. 8A) into the logical cell via the fourth probe, the clock signal being characterized by a clock frequency from about 1 MHz to about 10 GHZ, including subranges, fractions, and interpolations thereof. The d-flip flop cell can be powered via the first and second probes, coupled with the supply voltage node (e.g., supply voltage 820 of FIG. 8A) and the relative ground voltage node (e.g., relative ground voltage 825 of FIG. 8A), respectively.

At operation 635, example process 600 includes generating output data describing the one or more logical states of the logical cell over at least a portion of the operational test. Generating the output data can include coupling a voltage signal and/or a current signal (e.g., measured as a voltage across a load coupled with the output probe) out of the logical cell using the output probe landed at operation 625. The output data can include current data voltage data, for which a positive value of the output signal corresponds to a first logical state of the logical cell under test, and wherein a negative value of the output signal corresponds to a second logical state of the logical cell under test. As described in more detail in reference to FIGS. 7A-8D, and in reference to operation 625, a zero value of current and/or voltage measured at operation 635 can correspond to a fault in the logical cell, such as a fabrication defect (e.g., a short), a fault in the signal, or another improper logical state of the cell.

### Example 1: Voltage Inverter (not Gate) Cell

FIGS. 7A-7D illustrate an example voltage inverter cell 700 and example signals generated through interrogation of the inverter 700, in accordance with some embodiments of the present disclosure. FIG. 7A is a circuit diagram of the inverter cell 700, including an input node 705 ‘Vᵢₙ’ and an output node 710 ‘Vₒᵤₜ’ on opposing sides of an arrangement of transistors coupled to configure the transistors to invert the voltage of an input signal at the output node 710 when the cell 700 is powered at a supply voltage node 715 ‘Vdd’ and coupled to a reference ground node 720 ‘Vss.’ As shown in FIG. 7A, the power supply nodes 715 and 720 are electrically isolated from the surrounding power distribution nets, as described in more detail in reference to FIGS. 2A-2B. FIG. 7B represents a simplified diagram of the logical cell 700, omitting the power distribution nets and supply nodes 715 and 720.

FIGS. 7C-7D are data plots of an input signal and an inverted output signal, respectively. The data are normalized and at least partially denoised to simplify interpretation of the waveforms and the functioning of the logical cell 700 under interrogation using the techniques of the present disclosure (e.g., example process 600 of FIG. 6). FIG. 7C illustrates a substantially square waveform alternating between positive and negative output signals, with a mean approximately centered at zero.

As described in more detail in reference to FIG. 6, biasing the cell 700 in this way can improve the interrogation of logical states. In the case of powering an inverter cell with a Vss voltage about 0 V, as is typical, the output probe will generate negligible or no output across the NMOS leg of the circuit when the output is a logical Low. In this way, a functional issue with the NMOS transistor that results in a zero signal could be read as a logical state at the oscilloscope. Confounding nominal operation with a fault in the NMOS leg provides information on the function of the PMOS transistor, but not the NMOS transistor. To that end, biasing the Vss voltage to a negative value below 0 V enables systems of the present disclosure to test the entire circuit. In the example illustrated, the inverter cell is operating as designed, as demonstrated by the inverted sign of the normalized output signal in FIG. 7D as compared to the normalized input signal of FIG. 7C.

### Example 2: Flip-Flop Cell

FIGS. 8A-8D illustrate an example d-flip flop cell 800 and example signals generated through interrogation of the example cell, in accordance with some embodiments of the present disclosure. In practice, a d-flip-flop captures the value of a D-input (‘D’) 805 at a particular portion of the clock signal (CLK) 810, such as the rising edge of the CLK signal 810. That captured value becomes the Q output signal 815. At other times, the output Q 815 does not change. The D flip-flop 800 is an example of a memory cell, a zero-order hold, or a delay line. The example cell 800 is powered via electrically isolated distribution nets that couple with the constituent transistors of the cell 800 at various points in the diagram to provide a supply voltage 820 Vdd and a relative ground voltage 825 Vss. It is understood however, that the interconnections can be configured differently, for example, with more than two nets coupling the cell in the manner shown.

As in FIGS. 7C-7D, the data in FIGS. 8B-8D are normalized and at least partially denoised to simplify interpretation of the waveforms and the functioning of the logical cell 800 under interrogation using the techniques of the present disclosure (e.g., example process 600 of FIG. 6). As demonstrated in FIGS. 8B-8C, the cell flips between positive and negative voltages in accordance with the rising portion of the CLK signal 810 coinciding with a change in polarity of the D-input signal 805, in this way, the cell holds the last state change until the next flip that is initiated by the CLK signal 810. In this way, the cell 800 is shown to be operating as designed in the segment of input and output data shown.

In the preceding description, various embodiments have been described. For purposes of explanation, specific configurations and details have been set forth in order to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on integrated circuit testing systems, and multi-probe systems in particular, these are meant as non-limiting, illustrative embodiments. Embodiments of the present disclosure are not limited to such embodiments, but rather are intended to address analytical instruments systems for which a wide array of material samples can be analyzed by probes of the present disclosure, such as micro-biological samples (e.g., for physiological measurements) and/or nanostructured samples.

Some embodiments of the present disclosure include a system including one or more data processors and/or logic circuits. In some embodiments, the system includes a non-transitory computer readable storage medium containing instructions which, when executed on the one or more data processors and/or logic circuits, cause the one or more data processors and/or logic circuits to perform part or all of one or more methods and/or part or all of one or more processes and workflows disclosed herein. Some embodiments of the present disclosure include a computer-program product tangibly embodied in non-transitory machine-readable storage media, including instructions configured to cause one or more data processors and/or logic circuits to perform part or all of one or more methods and/or part or all of one or more processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the claims. Thus, it should be understood that although the present disclosure includes specific embodiments and optional features, modification and variation of the concepts herein disclosed may be resorted to by those skilled in the art, and that such modifications and variations are considered to be within the scope of the appended claims.

Where terms are used without explicit definition, it is understood that the ordinary meaning of the word is intended, unless a term carries a special and/or specific meaning in the field of charged particle microscopy systems or other relevant fields. The terms “about” or “substantially” are used to indicate a deviation from the stated property within which the deviation has little to no influence of the corresponding function, property, or attribute of the structure being described. In an illustrated example, where a dimensional parameter is described as “substantially equal” to another dimensional parameter, the term “substantially” is intended to reflect that the two parameters being compared can be unequal within a tolerable limit, such as a fabrication tolerance or a confidence interval inherent to the operation of the system. Similarly, where a geometric parameter, such as an alignment or angular orientation, is described as “about” normal, “substantially” normal, or “substantially” parallel, the terms “about” or “substantially” are intended to reflect that the alignment or angular orientation can be different from the exact stated condition (e.g., not exactly normal) within a tolerable limit. For numerical values, such as diameters, lengths, widths, or the like, the term “about” can be understood to describe a deviation from the stated value of up to ±10%. For example, a dimension of “about 10 mm” can describe a dimension from 9 mm to 11 mm.

The description provides exemplary embodiments, and is not intended to limit the scope, applicability or configuration of the disclosure. Rather, the ensuing description of the exemplary embodiments will provide those skilled in the art with an enabling description for implementing various embodiments. It is understood that various changes may be made in the function and arrangement of elements without departing from the spirit and scope as set forth in the appended claims. Specific details are given in the description to provide a thorough understanding of the embodiments. However, it will be understood that the embodiments may be practiced without these specific details. For example, specific system components, systems, processes, and other elements of the present disclosure may be shown in schematic diagram form or omitted from illustrations in order not to obscure the embodiments in unnecessary detail. In other instances, well-known circuits, processes, components, structures, and/or techniques may be shown without unnecessary detail.

What is claimed is:

1. A system for electrical characterization of a logical cell, the system comprising:
a plurality of probes;
control circuitry, electrically coupled with the probes;
bias circuitry, electrically coupled with one or more of the probes and configured to apply a bias voltage to the one or more probes; and
one or more machine-readable storage media, electronically coupled with the control circuitry, the media storing instructions that, when executed by a machine, cause the machine to perform operations comprising:
landing the probes on a surface of an integrated circuit, thereby electrically coupling the probes with the logical cell, comprising a plurality of electrically coupled transistors, the logical cell having been electrically isolated from one or more conductive structures of the integrated circuit;
applying one or more bias voltages to the logical cell via one or more of the probes, using the bias circuitry;
performing an operational test of the logical cell using the probes, wherein the plurality of transistors together defines an arrangement configured to generate an output voltage representative of one or more logical states of the logical cell in response to one or more input voltage signals, the operational test being based at least in part on the arrangement; and
generating output data describing the one or more logical states of the logical cell over at least a portion of the operational test.

2. The system of claim 1, wherein landing the probes comprises:
electrically coupling a first probe with a positive supply input of the logical cell; and
electrically coupling a second probe with a negative supply input of the logical cell,
wherein applying the bias voltages comprises coupling a positive bias voltage into the first probe and coupling a negative bias voltage into the second probe.

3. The system of claim 1, wherein landing the probes comprises electrically coupling a first probe with a transistor gate of the logical cell and a second probe with an output terminal of the logical cell.

4. The system of claim 3, wherein performing the operational test of the logical cell comprises coupling a test signal into the logical cell via first probe, and wherein generating the output data comprises coupling a voltage signal out of the logical cell from the fourth probe.

5. The system of claim 1, wherein the output data comprise voltage data, for which a positive value of the voltage corresponds to a first logical state of the logical cell under test, and wherein a negative value of the voltage corresponds to a second logical state of the logical cell under test.

6. The system of claim 5, wherein a zero value of the current corresponds to a fault in the signal.

7. The system of claim 1, wherein the arrangement defines a flip-flop, wherein the plurality of probes comprises eight or more probes, and wherein landing the probes comprises:
coupling a first probe with a positive supply input of the logical cell;
coupling a second probe with a negative supply input of the logical cell;
coupling a third probe with a test signal input, “D,” of the logical cell;
coupling a fourth probe with a clock signal input of the logical cell; and
coupling a fifth probe with an output of the logical cell.

8. The system of claim 7, wherein performing the operational test comprises:
coupling the test signal into the logical cell via the third probe, the test signal describing a duty cycle of the flip-flop; and
coupling the clock signal into the logical cell via the fourth probe, the clock signal being characterized by a clock frequency from about 1 MHz to about 10 GHZ,
and wherein generating the output data comprises coupling voltage data out of the logical cell from the fifth probe.

9. The system of claim 1, wherein the surface of the integrated circuit corresponds to a metallization layer of the integrated circuit, Mₙ, and wherein the integrated circuit defines a trench in the metallization layer Mₙ at least partially surrounding the logical cell.

10. The system of claim 9, wherein the trench is formed through a subordinate layer, Mₘ, below the metal layer Mₙ.

11. The system of claim 1, wherein the conductive structures comprise power distribution nets.

12. The system of claim 1, wherein a probe of the plurality of probes is coupled with a circuit element configured to improve a quality of an alternating current signal coupled into the logical cell via the probe.

13. A method for electrical characterization of a logical cell, the method comprising:
landing a plurality of probes on a surface of an integrated circuit, thereby electrically coupling the probes with the logical cell, comprising a plurality of electrically coupled transistors, the logical cell having been electrically isolated from one or more conductive structures of the integrated circuit;
applying one or more bias voltages to the logical cell via one or more of the probes, using bias circuitry, the bias circuitry being configured to apply a bias voltage to the one or more probes;
performing an operational test of the logical cell using the probes, wherein the plurality of transistors together defines an arrangement configured to generate an output voltage representative of one or more logical states of the logical cell in response to one or more input voltage signals, the operational test being based at least in part on the arrangement; and
generating output data describing the one or more logical states of the logical cell over at least a portion of the operational test.

14. The method of claim 13, wherein landing the probes comprises:
electrically coupling a first probe with a positive supply input of the logical cell; and
electrically coupling a second probe with a negative supply input of the logical cell,
and wherein applying the bias voltages comprises coupling a positive bias voltage into the first probe and coupling a negative bias voltage into the second probe.

15. The method of claim 13, wherein landing the probes comprises electrically coupling a first probe with a transistor gate of the logical cell and a second probe with an output terminal of the logical cell.

16. The method of claim 15, wherein performing the operational test of the logical cell comprises coupling a test signal into the logical cell via a first probe, and wherein generating the output data comprises coupling an output signal out of the logical cell from the fourth probe.

17. The method of claim 15, wherein the second probe is coupled with a load, and wherein the method comprises measuring a voltage across the load.

18. The method of claim 13, wherein the output data comprise voltage data, for which a positive value of the voltage corresponds to a first logical state of the logical cell under test, and wherein a negative value of the voltage corresponds to a second logical state of the logical cell under test.

19. The method of claim 18, wherein a zero value of the current corresponds to a fault in the signal.

20. The method of claim 13, wherein the arrangement defines a flip-flop, wherein the plurality of probes comprises eight or more probes, and wherein landing the probes comprises:
coupling a first probe with a positive supply input of the logical cell;
coupling a second probe with a negative supply input of the logical cell;
coupling a third probe with a test signal input, “D,” of the logical cell;
coupling a fourth probe with a clock signal input of the logical cell; and
coupling a fifth probe with a voltage output of the logical cell.

21. The method of claim 20, wherein performing the operational test comprises:
coupling the test signal into the logical cell via the third probe, the test signal describing a duty cycle of the flip-flop; and
coupling the clock signal into the logical cell via the fourth probe, the clock signal being characterized by a clock frequency from about 1 MHz to about 10 GHZ,
and wherein generating the generating the output data comprises coupling voltage data out of the logical cell from the fifth probe.

22. The method of claim 13, wherein the surface of the integrated circuit corresponds to a metallization layer of the integrated circuit, Mₙ, and wherein the integrated circuit defines a trench in the metallization layer Mₙ at least partially surrounding the logical cell.
